(19) United States
(12) Patent Application Publication
(10) Pub. No.: US 2015/0380297 A1
(43) Pub. Date: Dec. 31, 2015

(54) METHOD FOR MANUFACTURING MOSFET

(71) Applicant: INSTITUTE OF MICROELECTRONICS, CHINESE ACADEMY OF SCIENCES, Beijing (CN)

(72) Inventors: Haizhou YIN, Poughkeepsie, NY (US); Changliang QIN, Beijing (CN); Huilong ZHU, Poughkeepsie, NY (US)

(73) Assignee: The Institute of Microelectronics, Chinese Academy of Sciences

(21) Appl. No.: 14/759,324

(22) PCT Filed: Oct. 30, 2012
(86) PCT No.: PCT/CN2012/083748

§ 371 Date: Jul. 6, 2015

(30) Foreign Application Priority Data
Oct. 23, 2012 (CN) 201210407433.X

(51) Int. Cl. H01L 21/762; H01L 21/311; H01L 29/16; H01L 29/06; H01L 29/66

(52) U.S. Cl. CPC H01L 21/76232; H01L 29/0657; H01L 29/66636; H01L 29/665; H01L 29/1608; H01L 21/31144

(57) ABSTRACT

Provided is a method for manufacturing a MOSFET, comprising: epitaxially growing a first semiconductor layer on a semiconductor substrate; epitaxially growing a second semiconductor layer on the first semiconductor layer; forming a shallow trench isolation in the first semiconductor layer and the second semiconductor layer to define an active region for the MOSFET; forming on the second semiconductor layer a gate stack and a spacer surrounding the gate stack; forming openings in the second semiconductor layer using the shallow trench isolation, the gate stack and the spacer as a hard mask; epitaxially growing, in each of the openings, a third semiconductor layer using a bottom surface and sidewalls of the opening as a growth seed layer, wherein the third semiconductor layer comprises a material different from that of the second semiconductor layer; and performing ion implantation into the third semiconductor layer to form source and drain regions.

### CROSS-REFERENCE TO RELATED APPLICATION(S)

This application claims priority to Chinese Application No. 201210407433.X, filed on Oct. 23, 2012, entitled “METHOD FOR MANUFACTURING MOSFET,” which is incorporated herein by reference in its entirety.

### TECHNICAL FIELD

The present disclosure relates to a method for manufacturing a MOSFET, and in particular, to a method for manufacturing a MOSFET having enhanced stress.

### BACKGROUND

An important trend in the development of the integrated circuitry technology is scaling down of metal-oxide-semiconductor field effect transistors (MOSFETs) to improve integration level and reduce manufacturing cost. However, the performance of semiconductor materials (e.g., carrier mobility) and the performance of the MOSFETs (e.g., threshold voltage) may also deteriorate as the size of the MOSFETs decreases.

A MOSFET may have increased carrier mobility due to appropriate stress being applied to a channel region thereof, resulting in a reduced ON resistance and an enhanced switching speed of the device. When the device is an n-type MOSFET, tensile stress may be applied to the channel region along a longitudinal direction thereof and compressive stress may be applied to the channel region along a lateral direction thereof, so as to improve the mobility of electrons as the carriers. On the other hand, when the transistor is a p-type MOSFET, compressive stress may be applied to the channel region along the longitudinal direction thereof and tensile stress may be applied to the channel region along the lateral direction thereof, so as to improve the mobility of holes as the carriers.

Desirable stress can be generated by forming a source region and a drain region using a semiconductor material different from that of a semiconductor substrate. For the n-type MOSFET, Si:C source and drain regions formed on a Si substrate may function as a stressor which applies the tensile stress to the channel region along the longitudinal direction thereof. For the p-type MOSFET, SiGe source and drain regions formed on a Si substrate may function as a stressor, which applies the compressive stress to the channel region along the longitudinal direction thereof.

FIGS. 1-4 are schematic views showing semiconductor structures formed in various stages in a flow for manufacturing a MOSFET with enhanced stress according to a method of the prior art, in which FIGS. 1A, 2A, 3A and 4A show cross-section views of the respective semiconductor structures along a longitudinal direction of a channel region, FIGS. 3B and 4B show cross-section views of the respective semiconductor structures along a lateral direction of the channel region, and FIGS. 1B, 2B, 3C and 4C show top views of the respective semiconductor structures. In these figures, line AA represents a position where the cross-section views are taken along the longitudinal direction of the channel region, and line BB represents a position where the cross-section views are taken along the lateral direction of the channel region.

This method begins with the semiconductor structure shown in FIGS. 1A and 1B, in which a shallow trench isolation 102 is formed in a semiconductor substrate 101 to define an active region for the MOSFET. A gate stack surrounded by a spacer 105 is formed on the semiconductor substrate 101. The gate stack comprises a gate dielectric 103 and a gate conductor 104.

By using the shallow trench isolation 102, the gate conductor 104 and the spacer 105 as a hard mask, the semiconductor substrate 101 is etched to a desired depth so as to form openings in the semiconductor substrate at positions corresponding to a source region and a drain region, respectively, as shown in FIGS. 2A and 2B.

A semiconductor layer 106 is grown epitaxially on an exposed surface of the semiconductor substrate 101 within each of the openings so as to form the source region and the drain region. A portion of the semiconductor substrate 101, which is beneath the gate dielectric 103 and between the source region and the drain region functions as a channel region.

The semiconductor layer 106 is grown selectively from the surface of the semiconductor substrate 101. That is, the semiconductor layer 106 is grown at different growth rates on different crystalline surfaces of the semiconductor substrate 101. In an example in which the semiconductor substrate 101 comprises Si and the semiconductor layer 106 comprises SiGe, the semiconductor layer 106 has a slowest growth rate on a crystallographic plane {1 1 1} of the semiconductor substrate 101. As a result, the formed semiconductor layer 106 comprises not only a main plane (100) parallel to the surface of the semiconductor substrate 101, but also facets {1 1 1} at positions adjoining the shallow trench isolation 102 and the spacer 105, which is called an edge effect of the growth of the semiconductor layer 106, as shown in FIGS. 3A, 3B and 3C.

However, the small facets of the semiconductor layer 106 are not desirable because they cause more free surfaces, which release stress from the semiconductor, layer 106, thereby reducing the stress applied to the channel region.

Next, the surface of the semiconductor layer 106 is silicidated to form a metal silicide layer 107, as shown in FIGS. 4A, 4B and 4C. The silicidation consumes a part of the semiconductor layer 106. Due to the existence of the small facets of the semiconductor layer 106, the silicidation may occur along the small facets and finally may even reach the semiconductor substrate 101.

However, the silicidation in the semiconductor substrate 101 is undesirable because it may form the metal silicide in a junction region, which leads to increased junction leakage.

Thus, it is desirable to suppress the edge effect in the semiconductor layer of the source and drain regions in the MOSFET with enhanced stress.

### SUMMARY

The present disclosure aims to provide, among other, a method for manufacturing a MOSFET with enhanced channel stress and/or reduced junction leakage.

According to an aspect of the present disclosure, there is provided a method for manufacturing a MOSFET, comprising: epitaxially growing a first semiconductor layer on a semiconductor substrate; epitaxially growing a second semiconductor layer on the first semiconductor layer; forming a shallow trench isolation in the first semiconductor layer and the second semiconductor layer to define an active region for the MOSFET; forming on the second semiconductor layer a gate stack and a spacer surrounding the gate stack; forming openings in the second semiconductor layer using the shallow trench isolation, the gate stack and the spacer as a hard mask; epitaxially growing, in each of the openings, a third semiconductor layer using a bottom surface and sidewalls of the opening as a growth seed layer, wherein the third semiconductor layer comprises a material different from that of the second semiconductor layer; and performing ion implantation into the third semiconductor layer to form a source/drain region.

According to this method, stress can be applied to a channel region in the second semiconductor layer by the source region and the drain region made of the third semiconductor layer. Since the bottom surface and sidewalls of the opening is taken as the growth seed layer during the epitaxial growth, the third semiconductor layer may fill up the opening in the second semiconductor layer completely. The third semiconductor layer may have a {1 1 1} facet only present in a subsequently grown portion thereof, thereby suppressing the edge effect.

### BRIEF DESCRIPTION OF THE DRAWINGS

FIGS. 1-4 are schematic views showing semiconductor structures formed in various stages in a flow for manufacturing a MOSFET with enhanced stress according to a method of the prior art, in which FIGS. 1A, 2A, 3A and 4A show cross-section views of the respective semiconductor structures along a longitudinal direction of a channel region, FIGS. 3B and 4B show cross-section views of the respective semiconductor structures along a lateral direction of the channel region, and FIGS. 1B, 2B, 3C and 4C show top views of the respective semiconductor structures.

FIGS. 5-12 are schematic views showing semiconductor structures formed in various stages in a flow for manufacturing a MOSFET with enhanced stress according to an embodiment of the present disclosure, in which FIGS. 5-8, 9A, 10A, 11A, and 12A show cross-section views of the respective semiconductor structures along a longitudinal direction of a channel region, FIGS. 11B and 12B show cross-section views of the respective semiconductor structures along a lateral direction of the channel region, and FIGS. 9B, 10B, 11C and 12C show top views of the respective semiconductor structures.

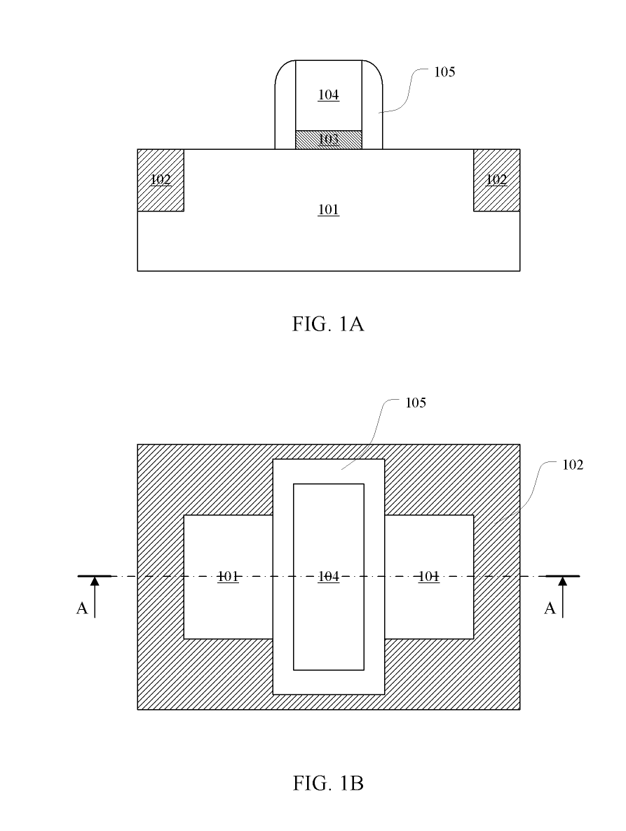

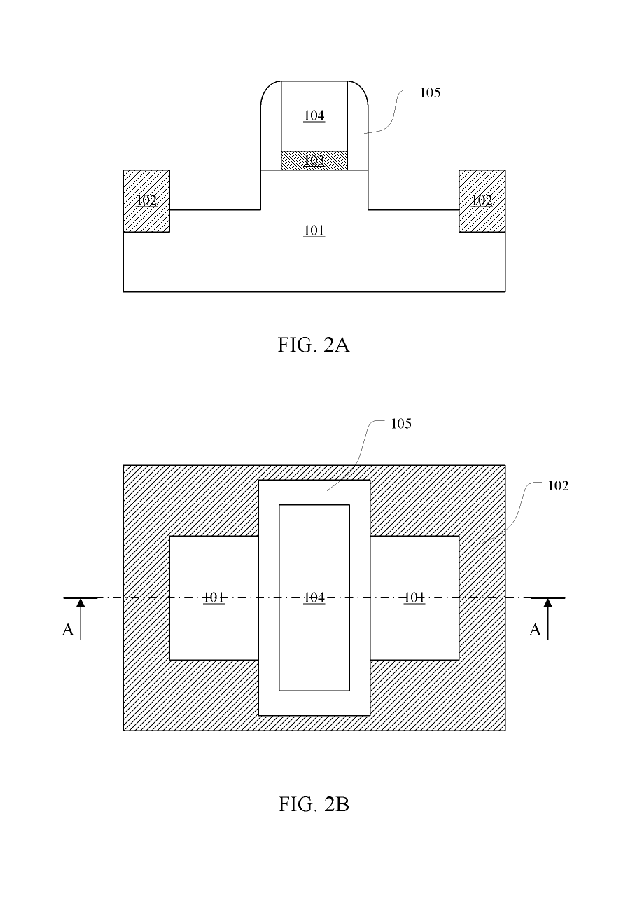

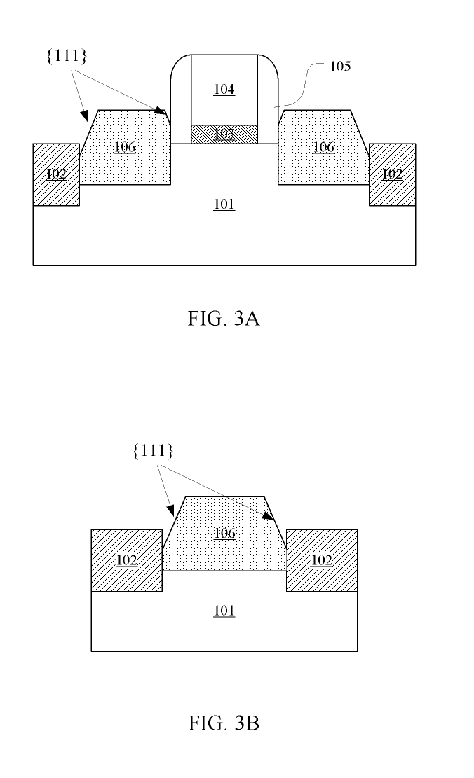

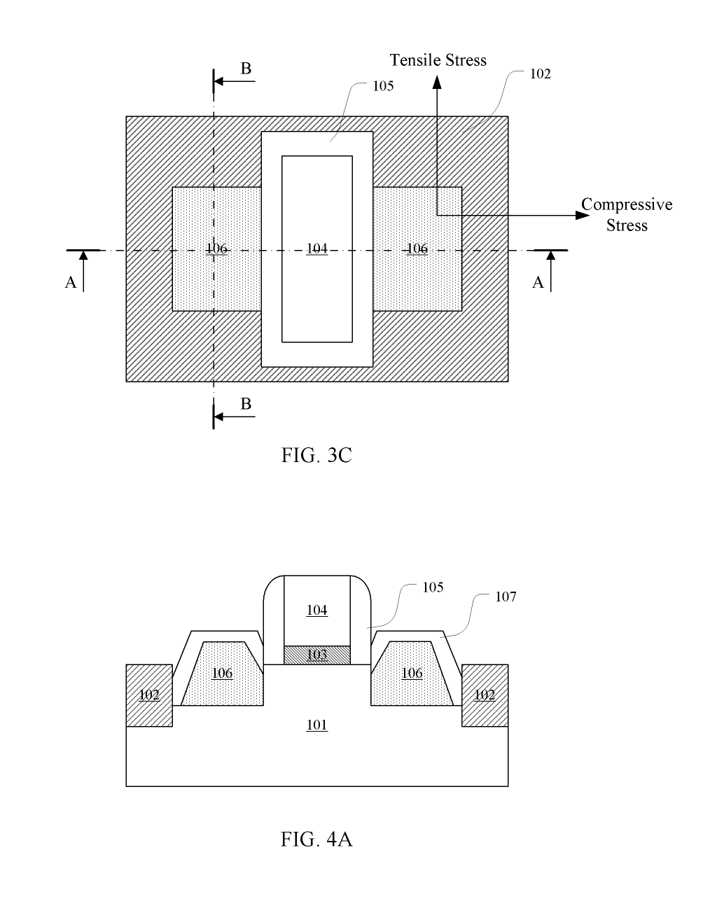

### DETAILED DESCRIPTION

Exemplary embodiments of the present disclosure are described in detail below with reference to the accompanying drawings. In the drawings, like reference numerals denote like elements. The figures are not necessarily drawn to scale, for the sake of clarity.

A semiconductor structure obtained by several steps may be illustrated in one figure, for the sake of conciseness.

In descriptions of structures, when one layer or region is referred to as being “above” or “on” another layer or region, it can be directly above or on the other layer or region, or other layer(s) or region(s) may be arranged there between. Moreover, if the structure in the figures is turned over, the layer or region will be “under” or “below” the other layer or region.

In order to illustrate a situation in which one layer or region is directly on another layer or region, expressions such as “directly on” or “on and adjoining” may be utilized.

In the present disclosure, the term “semiconductor structure” refers generally to an entire semiconductor structure formed through various steps, which have been performed, of a method for manufacturing a semiconductor device, including all of the layers and regions that have been formed. The term “a longitudinal direction of a channel region” refers to a direction from a source region to a drain region or vice versa. The term “a lateral direction of a channel region” refers to a direction perpendicular to the longitudinal direction of the channel region in a plane parallel to a main surface of a semiconductor substrate. For example, for a MOSFET formed on a {1 0 0} silicon wafer, the longitudinal direction of the channel region is typically along a <110> direction of the silicon wafer and the lateral direction of the channel region is typically along a <011> direction of the silicon wafer.

Next, some particular details of the disclosure, such as exemplary structures, materials, dimensions, process steps and technologies, will be described for a better understanding of the present disclosure. Nevertheless, it should be understood by one skilled person in the art that the disclosure can be implemented without these details.

Unless indicated otherwise, each part of a MOSFET can be made of material(s) well-known to one skilled person in the art. A semiconductor material may comprise, for example, a III-Vgroup semiconductor material such as GaAs, InP, GaN and SiC, or a IVgroup semiconductor such as Si and Ge. A gate conductor may comprise any of various conductive materials, for example, metal, doped polysilicon, a multilayer gate conductor including a metal layer and a doped polysilicon layer, or any other conductive material, such as TaC, TiN, TaTbN, TaErN, TaYbN, TaSiN, HfSiN, MoSiN, RuTax, NiTax, MoNx, TiSiN, TiCN, TaAlC, TiAlN, TaN, PtSix, Ni₃Si, Pt, Ru, Ir, Mo, HfRu, RuOx, or any combination thereof. A gate dielectric may comprise SiO₂ or any other dielectric material which has a dielectric constant greater than that of SiO₂, such as oxide, nitride, oxynitride, silicate, aluminate, or titanate. The oxide may include, for example, SiO₂, HfO₂, ZrO₂, Al₂O₃, TiO₂, or La₂O₃. The nitride may include, for example, Si₃N₄. The silicate may include, for example, HfSiOx. The aluminate may include, for example, LaAlO₃. The titanate may include, for example, SrTiO₃. The oxynitride may include, for example, SiON. Moreover, the gate dielectric may comprise any material that will be developed in the future, besides the above known materials.

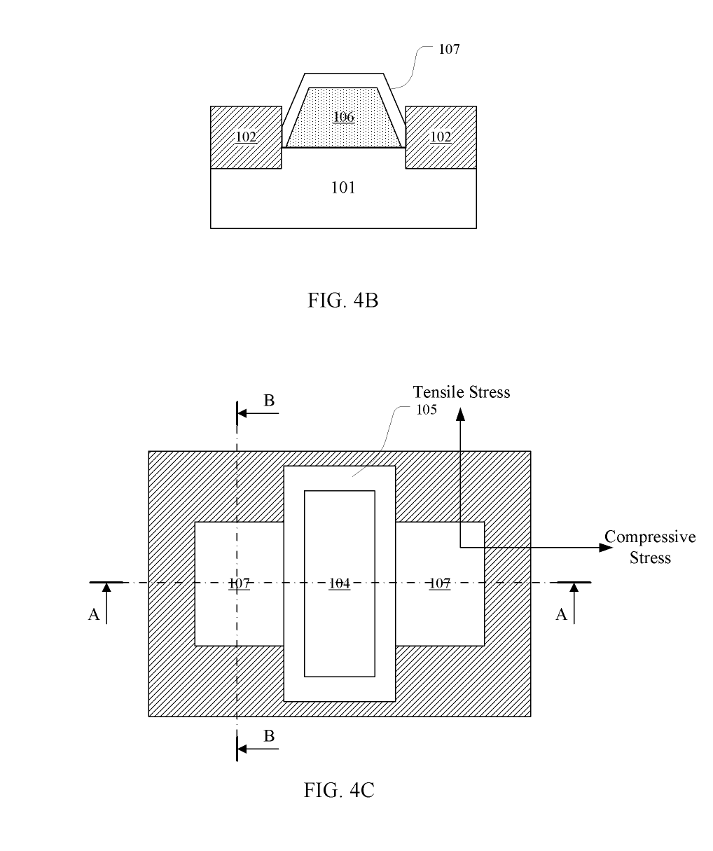

According to embodiments of the present disclosure, a MOSFET with enhanced stress is manufactured by the following steps, which are described with reference to FIGS. 5-12. The figures schematically show cross-section views of semiconductor structures obtained in various stages of the method. Top views are shown as necessary in the figures, in which line AA represents a position where the cross-section views are taken along a longitudinal direction of a channel region and line BB represents a position where the cross-section views are taken along a lateral direction of a channel region.

The method begins with a semiconductor structure shown in FIG. 5, in which a first semiconductor layer 202, a second semiconductor 203, a pad oxide layer 204 and a pad nitride layer 205 are formed in sequence on a semiconductor substrate 201. The semiconductor substrate 201 may comprise Si, for example. The first semiconductor layer 202 may be an epitaxially-grown layer, which may comprise SiGe having a Ge atomic percentage of about 10-15% and have a thickness of about 30-50 nm, for example. The second semiconductor layer 203 may be an epitaxially-grown layer, which may comprise Si and have a thickness of about 100-200 nm, for example. The pad oxide layer 204 may comprise silicon oxide and have a thickness of about 2-5 nm, for example. The padnitride layer 205 may comprise silicon nitride and have a thickness of about 10-50 nm, for example. The pad oxide layer 204 may decrease stress between the second semiconductor layer 203 and the pad nitride layer 205 as well known. The pad nitride layer 205 may be used as a hard mask in a subsequent etching step.

The respective layers described above may be formed by known processes. The first semiconductor layer 202 and the second semiconductor layer 203 may be grown epitaxially by a known deposition process, such as EBM (Electron Beam Evaporation), CVD (Chemical Vapor Deposition), ALD (Atomic Layer Deposition), or sputtering. The pad oxide layer 204 may be formed by thermal oxidization, for example. The pad nitride layer 205 may be formed by Chemical Vapor Deposition, for example.

Then, a photoresist layer (not shown) is formed on the pad nitride layer 205 by spin-coating and the photoresist layer is subjected to a photolithography process including exposure and development to form a pattern for a shallow trench isolation. By using the photoresist layer as a mask, exposed portions of the pad nitride layer 205 and the pad oxide layer 204 are removed in sequence by dry etching such as ion milling, plasma etching, reactive ion etching, or laser ablation, or wet etching using an etching agent solution. The etching stops on a surface of the second semiconductor layer 203 and forms a pattern of the shallow trench isolation in the pad nitride layer 205 and the pad oxide layer 204. The photoresist layer is removed by ashing or being dissolved in a solvent.

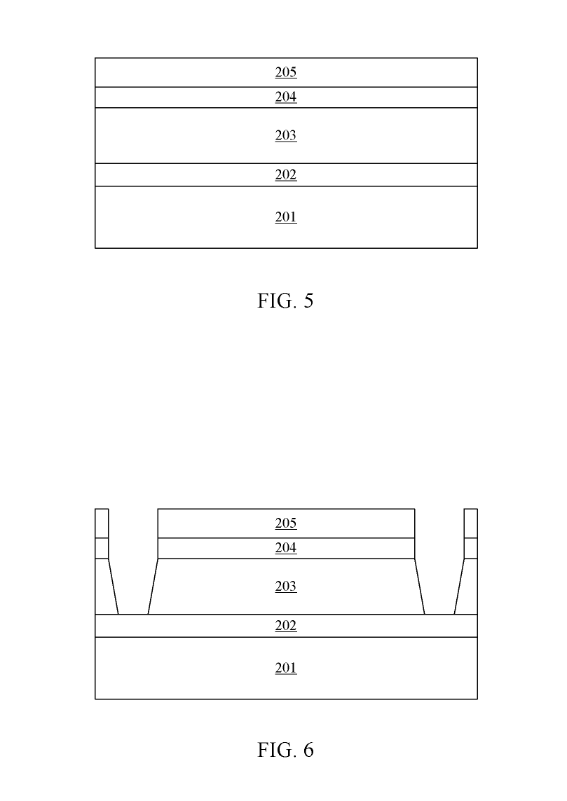

By using the pad nitride 205 and the pad oxide layer 204 together as a hard mask, an exposed portion of the second semiconductor layer 203 is removed by known dry etching or wet etching so as to form a first portion of a shallow trench in the second semiconductor layer 203, as shown FIG. 6. The etching selectively removes the material of the second semiconductor layer 203 with respect to the first semiconductor layer 202, and stops at a surface of the first semiconductor layer 202. In addition, the etching is anisotropic so that by choosing appropriate etchant and etching conditions, an upper portion of the first portion of the shallow trench has a width greater than that of a lower portion thereof. That is, the first portion of the shallow trench has slant sidewalls. Preferably, an angle between a top surface of the first portion of the shallow trench and the sidewall is less than 70°. It should be noted that the shape of the shallow trench obtained by the etching may be varied by choosing appropriate etchant and etching conditions, so that the shallow trench may have steep or slant sidewalls.

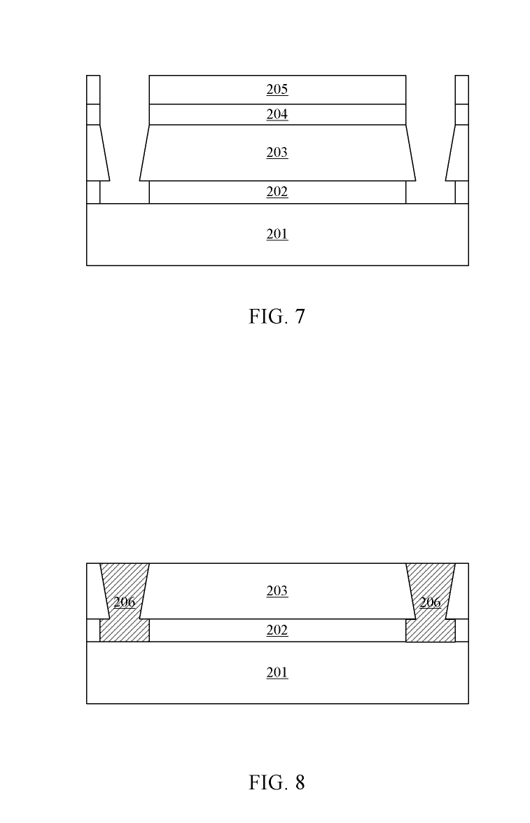

Then, an exposed portion of the first semiconductor layer 202 is removed via the first portion of the shallow trench by dry etching or wet etching, thereby forming a second portion of the shallow trench in the first semiconductor layer 202, as shown in FIG. 7. This etching selectively removes the material of the first semiconductor layer 202 with respect to the second semiconductor layer 203 and the semiconductor substrate 201, and stops at a surface of the semiconductor substrate 201. In addition, this etching is isotropic so that the second portion of the shallow trench is not only present right below the first portion of the shallow trench, but also extends partially to beneath the second semiconductor layer 203.

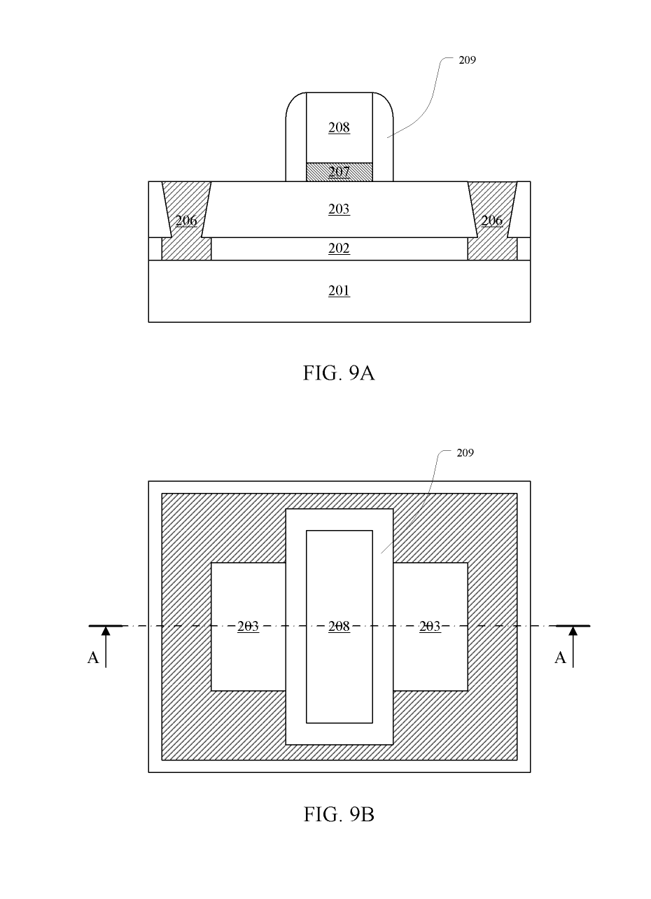

Next, an insulating material layer (not shown) is formed on a surface of the resultant semiconductor structure by deposition. The insulating material layer fills the first portion and the second portion of the shallow trench. Portions of the insulting material layer outside the shallow trench are removed by CMP (Chemical Mechanical Polishing), and the pad nitride layer 203 and the pad oxide layer 204 are further removed. The portion of the insulating material remaining in the shallow trench forms the shallow trench isolation 206, as shown in FIG. 8. The shallow trench isolation 206 defines an active region for the MOSFET, and comprises first and second portions, which correspond to the first and second portions of the shallow trench, respectively. The first portion of the shallow trench isolation 206 has a slant sidewall, by which a portion of the second semiconductor layer 203 adjacent to the shallow trench isolation 206 can be reserved in a subsequent etching step. The second portion of the shallow trench isolation 206 expands the bottom of the shallow trench isolation 206, thereby improving its electrical insulating performance.

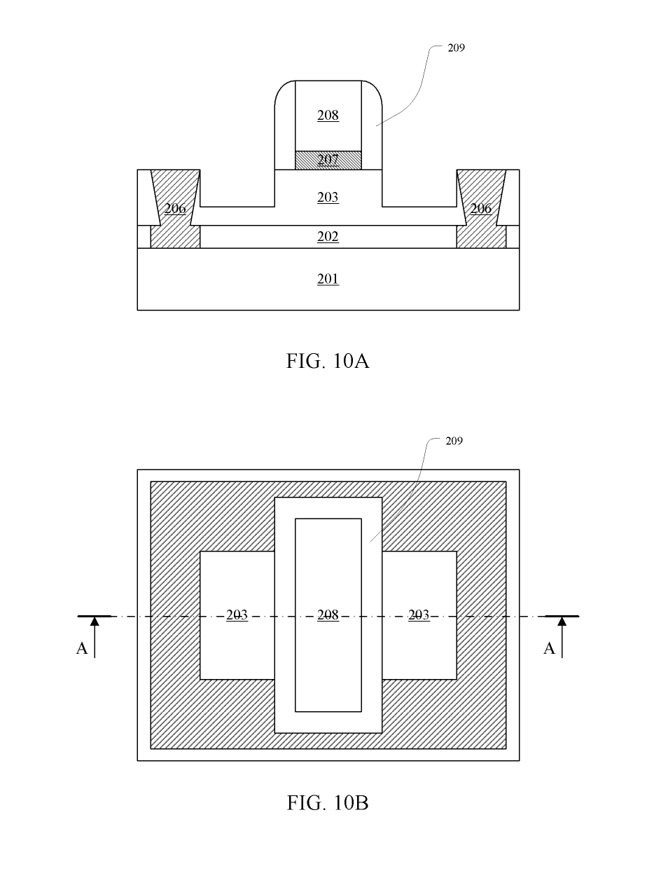

A dielectric layer and a poly silicon layer are formed in turn on a surface of the resultant semiconductor structure by deposition, and then patterned to form a gate stack including a gate dielectric 207 and a gate conductor 208. Next, a nitride layer with a thickness of for example 10-50 nm is deposited on the whole surface of the semiconductor structure by any of the above described processes, and then etched anisotropically to form a spacer 209 surrounding the gate stack, as shown in FIGS. 9A and 9B.

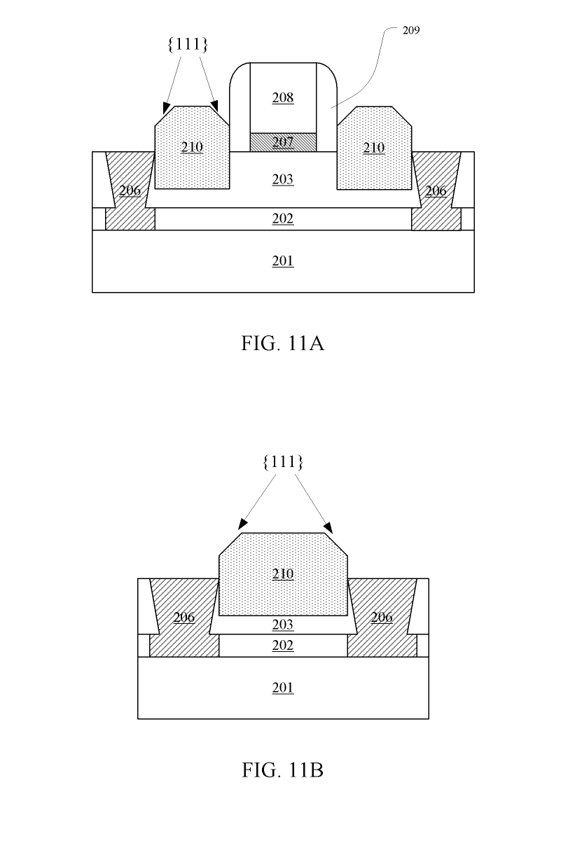

By using the shallow trench isolation 206, the gate conductor 208 and the spacer 209 as a hard mask, the second semiconductor layer 203 is etched to a desired depth, so as to form openings in the second semiconductor layer at positions corresponding to source and drain regions, as shown in FIGS. 10A and 10B. The etching is anisotropic, and appropriate etchant and etching conditions are chosen so that the openings each have a shape substantially consistent with that of the hard mask. That is to say, the openings each have an upright sidewall. Since the sidewall of the first portion of the shallow trench isolation 206 is slant, a portion of the second semiconductor layer 203 adjacent to the shallow trench isolation 206 may be reserved. Thus, each of the openings has all its side walls and bottom surface made of the material of the second semiconductor layer 203.

Next, a third semiconductor layer 210 is epitaxially grown within each of the openings in the second semiconductor layer 203. The third semiconductor layer 210 is selectively grown from the bottom surface and the sidewalls of the opening in the second semiconductor layer 203. That is to say, the third semiconductor layer 210 is grown at different rates on different crystalline surfaces of the second semiconductor layer 203. In an example in which the second semiconductor layer 203 comprises Si and the third semiconductor layer 210 comprises SiGe, the third semiconductor layer 210 is grown slowest on a crystalline surface {1 1 1} of the second semiconductor layer 203. However, unlike the prior art, the bottom surface and sidewalls of the opening in the second semiconductor layer 203 functions as the growth seed layer, and thus the third semiconductor layer 210 may completely fill up the opening in the second semiconductor layer 203.

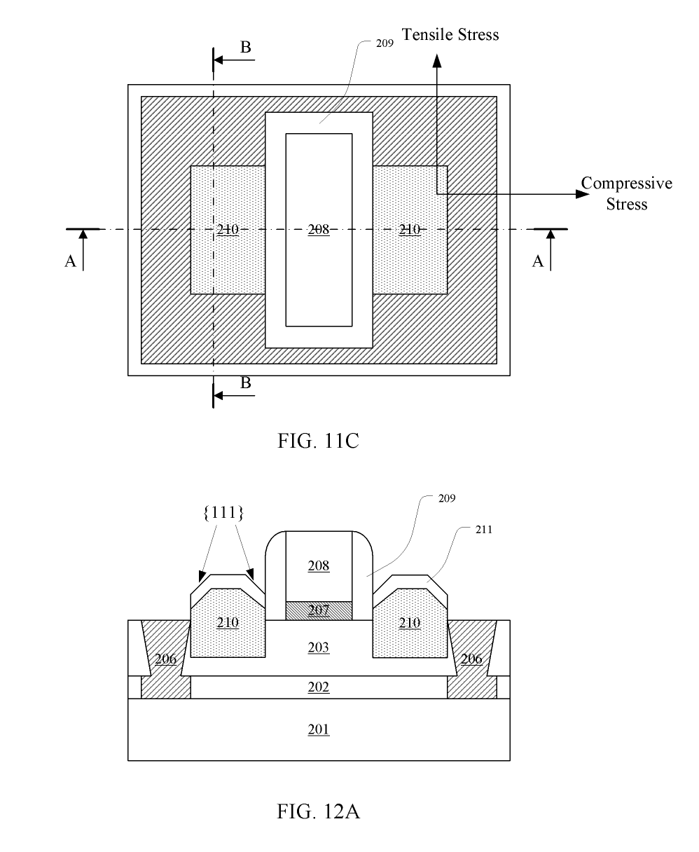

After completely filling up such the openings, the third semiconductor layer 210 loses the growing seed layer on the sidewalls of the openings, and thus continues being freely epitaxially grown. As a result, the continuously grown portion of the third semiconductor layer 210 comprises not only a main surface of (100) parallel to the surface of the second semiconductor layer 203, but also {1 1 1} facets at positions adjacent to the shallow trench isolation 206 and the spacer 209, as shown in FIGS. 11A, 11B and 11C.

The {1 1 1} facet of the third semiconductor layer 210 is only present within its continuously grown portion. The portion of the third semiconductor layer 210 within the opening of the second semiconductor layer 203 has its bottom surface and sidewalls constrained. Thus, the facets of the third semiconductor layer 203 would not disadvantageously affect the stress applied to the channel region.

Although not shown, after steps shown in FIGS. 5-11, ion implantation is implemented into the third semiconductor layer 210, and spike anneal may be implemented at a temperature of about 1000-1080° C. to activate dopants implanted in the previous implantation step and eliminate damages caused by the implantation, so as to form the source region and the drain region. A portion of the second semiconductor layer 203 below the gate dielectric 207 and between the source and drain regions functions as the channel region.

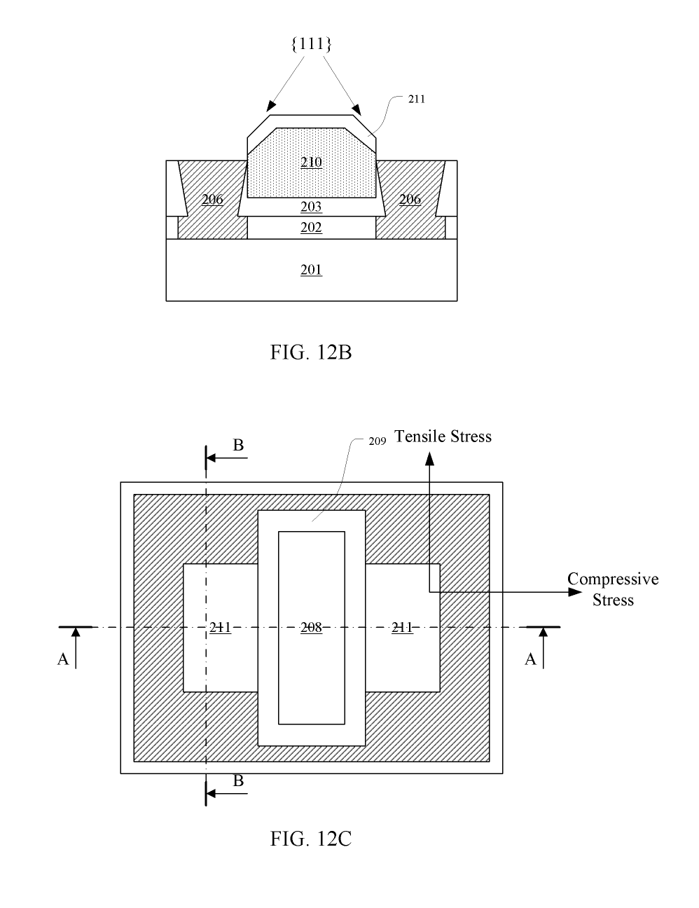

Preferably, silicidation is implemented at the surface of the third semiconductor layer 210 to form a metal silicide layer 211 so as to decrease a contact resistance of the source and drain regions, as shown in FIGS. 12A, 12B and 12C.

The process of silicidation is known per se. For example, a Ni layer with a thickness of about 5-12 nm is deposited firstly and then is thermally treated at 300-500° C. for 1-10 seconds, so that the surface portion of the third semiconductor layer 210 forms NiSi. Finally, the unreacted Ni is etched by wet etching.

The silicidation consumes some of the semiconductor material of the third semiconductor layer 210. Since there are the facets of the third semiconductor layer 210, the silicidation can occur along the facets. Since the third semiconductor layer 210 completely fills up the openings in the second semiconductor layer 203, the silicidation does not reach the second semiconductor layer 203.

After the step shown in FIG. 12, other components of the MOSFET, such as an interlayer insulating layer, a via in the interlayer insulating layer and a wiring or electrode on an upper surface of the interlayer insulating layer, are formed on the resultant semiconductor structure.

Although the above embodiment illustrates the p-type MOSFET with enhanced stress and the material for the stressor used therein, the present disclosure is also applicable to an n-type MOSFET with enhanced stress. In the n-type MOSFET, the third semiconductor layer 210 comprises, for example, Si:C to form the source and drain regions, and functions as a stressor for applying tensile stress to the channel region along the longitudinal direction thereof. Except for the different materials for the stressor, the n-type MOSFET with enhanced stress may be manufactured in a way similar to the above mentioned one.

The above descriptions are provided only to exemplify and illustrate the present disclosure, but are not intended to limit the present disclosure. Thus, the present disclosure is not limited to the illustrated embodiments. Any variant or modification apparent for those skilled in the art falls in the scope of the present disclosure.

I/we claim:

1. A method for manufacturing a MOSFET, comprising:
epitaxially growing a first semiconductor layer on a semiconductor substrate;
epitaxially growing a second semiconductor layer on the first semiconductor layer;
forming a shallow trench isolation in the first semiconductor layer and the second semiconductor layer to define an active region for the MOSFET;
forming on the second semiconductor layer a gate stack and a spacer surrounding the gate stack;
forming openings in the second semiconductor layer using the shallow trench isolation, the gate stack and the spacer as a hard mask;
epitaxially growing, in each of the openings, a third semiconductor layer using a bottom surface and sidewalls of the opening as a growth seed layer, wherein the third semiconductor layer comprises a material different from that of the second semiconductor layer; and
performing ion implantation into the third semiconductor layer to form source and drain regions.

2. The method according to claim 1, wherein a portion of the shallow trench isolation in the second conductor layer has a slant sidewall.

3. The method according to claim 2, wherein a portion of the shallow trench isolation in the first semiconductor layer extends to beneath the second semiconductor layer.

4. The method according to claim 3, wherein forming the shallow trench isolation comprises:
forming a hard mask including a pattern of the shallow trench isolation on the second semiconductor layer;
forming a first portion of a shallow trench in the second semiconductor layer by anisotropic etching, so that the first portion of the shallow trench has a slant sidewall and reaches a surface of the first semiconductor layer;
forming a second portion of the shallow trench in the first semiconductor layer by isotropic etching, so that the second portion of the shallow trench extends partially to beneath the second semiconductor layer; and
filling the shallow trench with an insulating material to form the shallow trench isolation.

5. The method according to claim 2, wherein an angle between a top surface of the first portion of the shallow trench isolation and the sidewall is less than 70°.

6. The method according to claim 1, wherein forming the openings comprises:
forming the openings in the second semiconductor layer by anisotropic etching so that the openings each have an upright sidewall.

7. The method according to claim 1, wherein the MOSFET comprises a p-type MOSFET.

8. The method according to claim 7, wherein the first semiconductor layer comprises SiGe, the second semiconductor layer comprises Si, and the third semiconductor layer comprises SiGe.

9. The method according to claim 1, wherein the MOSFET comprises an n-type MOSFET.

10. The method according to claim 9, wherein the first semiconductor layer comprises Si:C, the second semiconductor layer comprises Si, and the third semiconductor layer comprises Si:C.

11. The method according to claim 1, wherein after forming the source and drain regions, the method further comprises:
forming metal silicide on a surface of the source and drain regions by silicidation.
